(19) United States
(12) Patent Application Publication
(10) Pub. No.: US 2025/0376788 A1
(43) Pub. Date: Dec. 11, 2025

(54) Series of Fluorine-containing Rare Earth Borate Compounds, and Fluorine-containing Rare Earth Borate Nonlinear Optical Crystals as well as Preparation Method and Application Thereof

(71) Applicant: TIANJIN UNIVERSITY OF TECHNOLOGY, Tianjin (CN)

(72) Inventors: Hongwei YU, Tianjin (CN); Zhijun WEI, Tianjin (CN); Hongping WU, Tianjin (CN); Zhanggui HU, Tianjin (CN)

(21) Appl. No.: 19/301,897

(22) Filed: Aug. 15, 2025

Related U.S. Application Data
(63) Continuation of application No. PCT/CN2023/089996, filed on Apr. 23, 2023.

(30) Foreign Application Priority Data
Mar. 24, 2023 (CN) 2023103013996

(51) Int. Cl. C30B 29/22; C30B 7/04; C30B 9/12

(52) U.S. Cl. CPC C30B 29/22; C30B 7/04; C30B 9/12

(57) ABSTRACT

The present invention relates to compounds and their nonlinear optical (NLO) crystals of A₂REB₃O₆F₂ (A=Rb, Cs, NH₄; RE=Sc, Y, La), their producing method and uses thereof. The series of compounds have a chemical formula of A₂REB₃O₆F₂ (A=Rb, Cs, NH₄; RE=Sc, Y, La), which are namely Rb₂ScB₃O₆F₂, Cs₂ScB₃O₆F₂, (NH₄)₂ScB₃O₆F₂, Rb₂YB₃O₆F₂, Cs₂YB₃O₆F₂, (NH₄)₂YB₃O₆F₂, Rb₂LaB₃O₆F₂, Cs₂LaB₃O₆F₂ and (NH₄)₂LaB₃O₆F₂. The series of NLO crystals having the chemical formula of A₂REB₃O₆F₂ (A=Rb, Cs, NH₄; RE=Sc, Y, La), belong to orthorhombic crystal system, and have a space group of Amm2, crystal cell parameters of a=2.7182(4)−4.9617(8)Å, b=7.7013(5)−9.9742(6)Å, c=10.2634(1)−12.904(3)Å, Z=2. A₂REB₃O₆F₂ (A=Rb, Cs, NH₄; RE=Sc, Y, La) compounds were prepared by a solid-state reaction method or a hydrothermal method, and A₂REB₃O₆F₂ (A=Rb, Cs, NH₄; RE=Sc, Y, La) NLO crystals were prepared by a high-temperature solution method, a hydrothermal method, or a solution method. They meet the requirements for the frequency conversion of UV wavelength lasers and could be used to prepare nonlinear optical devices.

### CROSS REFERENCE TO RELATED APPLICATION

The present invention relates to fluorine-containing rare-earth borate compounds with a chemical formula of A₂REB₃O₆F₂ (A=Rb, Cs, NH₄; RE=Sc, Y, La), fluorine-containing rare-earth borate nonlinear optical crystals, a preparation method of the crystals and a nonlinear optical apparatus manufactured from the crystals.

### BACKGROUND OF THE INVENTION

Deep-ultraviolet (DUV) coherent lights with wavelengths below 200 nm are of increasing importance owing to their potential applications in semiconductor photolithography, laser micromachining, modern scientific instruments. For solid-state lasers, the best way to obtain the DUV coherent lights is through the cascaded frequency conversion technology of nonlinear optical (NLO) crystals. However, for an applicable DUV NLO crystal, it must satisfy the following harsh structural and properties' requirements, including i) the non-centrosymmetric (NCS) structures; ii) large second-order NLO coefficients (dᵢⱼ), at least comparable to the d₃₆ of KDP; iii) high transparency in the DUV region with the UV cut-off edge as short as possible; iv) a moderate birefringence (Δn=0.05-0.10) to satisfy the phase-matching condition of second-harmonic generation (SHG) in the UV or DUV region; and v) ease of growth, non-toxic, chemical stability, and good mechanical properties. However, since some of the above properties are conflicted, e.g., the materials with large band gaps often exhibit small SHG responses and birefringence, designing and synthesizing a DUV NLO crystal is still a great challenge. An extensive search for new phases in fluorine-containing rare-earth borates has led to several new deep-UV NLO crystals, A₂REB₃O₆F₂ (A=Rb, Cs, NH₄; RE=Sc, Y, La).

Fluorine-containing rare-earth borates with asymmetric [Y—O—F] polyhedron as well as π-conjugated [B₃O₆]³⁻ primitive as basic structural units usually have large band gaps and are widely considered as candidates for exploring UV or DUV optical crystals. Notably, BBO has a strong second harmonic response (6×KDP), with UV cut-off edge up to 189 nm. However, due to the problem of phase transition at 925° C. and the relatively long UV cut-off edge, the crystal cannot be used as a DUV nonlinear optical crystal. However, the [Y—O—F] polyhedron with large optical anisotropy is not only beneficial to improve the birefringence of the material, but also can be connected to other groups in the structure to form a 3D frame, which can further shorten the UV cut-off edge. Therefore, design and synthesis of fluorine-containing rare-earth borates with asymmetric [Y—O—F] polyhedrons and π-conjugated [B₃O₆]³⁻ units is an effective means to design DUV nonlinear optical materials.

### SUMMARY OF THE INVENTION

The first objective of the present invention is to provide fluorine-containing rare-earth borate compounds with a chemical formula of A₂REB₃O₆F₂ (A=Rb, Cs, NH₄; RE=Sc, Y, La). The series of single crystals belong to orthorhombic crystal system, and have a space group of Amm2, crystal cell parameters of a=2.7182(4)−4.9617(8)Å, b=7.7013(5)−9.9742(6)Å, c=10.2634(1)−12.904(3)Å, Z=2. The polycrystalline powder was prepared through a solid-state reaction method or a hydrothermal method.

The second objective of the present invention is to provide fluorine-containing rare-earth borate nonlinear optical crystals and a preparation method thereof. The crystals have a chemical formula of A₂REB₃O₆F₂ (A=Rb, Cs, NH₄; RE=Sc, Y, La), and belong to orthorhombic crystal system, as well as have a space group of Amm2, crystal cell parameters of a=2.7182(4)−4.9617(8)Å, b=7.7013(5)−9.9742(6)Å, c=10.2634(1)−12.904(3)Å, Z=2. The preparation methods are high-temperature solution method, hydrothermal method, and solution method.

The third objective of the present invention is to provide the use of fluorine-containing rare-earth borate nonlinear optical apparatus in nonlinear optical devices such as second harmonic generators, up and down frequency converters, optical parametric oscillations, laser frequency conversion devices, and laser communications.

The present invention adopts the following technical solution:

The fluorine-containing rare-earth borates nonlinear optical crystals provided by the present invention have a chemical formula of A₂REB₃O₆F₂ (A=Rb, Cs, NH₄; RE=Sc, Y, La). The series of single crystals belong to orthorhombic crystal system, and have a space group of Amm2, a=2.7182(4)−4.9617(8)Å, b=7.7013(5)−9.9742(6)Å, c=10.2634(1)−12.904(3)Å, Z=2. The preparation processes adopt a high-temperature solution method, a hydrothermal method or a solution method based on the following steps:

The high-temperature solution method is used to prepare A₂REB₃O₆F₂ (A=Rb, Cs, NH₄; RE=Sc, Y, La) nonlinear optical crystals, comprising the following steps:

a. Uniformly mixed the fluorine-containing rare-earth borate compounds single-phase polycrystalline powder with the fluxing agents, and heated it to a temperature of 400-1000° C., and kept it at a constant temperature for a period of time to obtain a mixed melt, and then cooled to 300-900° C., in which the molar ratios of the fluorine-containing rare-earth borate compounds single-phase polycrystalline powder to the fluxing agents are 1:0-50.

Or directly heat the mixture of a A-containing compound (A=Rb, Cs, NH₄), a RE-containing compound (RE=Sc, Y, La), a boron-containing compound, a fluorine-containing compound or the mixture of a A-containing compound (A=Rb, Cs, NH₄), a RE-containing compound (RE=Sc, Y, La), a boron-containing compound, a fluorine-containing compound and the fluxing agents to 400-1000° C., and held at this temperature for a period of time to obtain a mixed melt. And then cooled to a temperature of 300-900° C., in which the molar ratios of a A-containing compound (A=Rb, Cs, NH₄), a RE-containing compound (RE=Sc, Y, La), a boron-containing compound, a fluorine-containing compound and fluxing agents are 1.5-2.2:0.8-1.5:2.5-3.5:1.5-2.2:0-50.

The A-containing compounds (A=Rb, Cs, NH₄) include at least one or more of AOH, A₂O and alkali metal salt; alkali metal salt includes at least one or more of AF, ACl, ABr, ANO₃, A₂C₂O₄, A₂CO₃, AHCO₃, A₂SO₄, wherein A=Rb, Cs, NH₄;

The RE-containing compounds (RE=Sc, Y, La) include at least one or more of RE₂O₃, REF₃, RE(NO₃)₃·6H₂O;

The boron-containing compounds include at least one or more of B₂O₃, H₃BO₃ and boron salt; the boron salt includes at least one or more of ABO₂, ABO₃, A₃BO₃, A₂B₄O₇, wherein A=Rb, Cs, NH₄;

The fluorine-containing compounds include at least one or more of AF, REF₃, wherein A=Rb, Cs, NH₄; RE=Sc, Y, La, and other fluorine-containing compounds include at least one or more of KBF₄, NaBF₄, KPF₆ and NH₄PF₆.

The fluxing agents mainly include at least one or more of alkali metal salts, i.e., alkali metal carbonates, alkali metal nitrates, alkali metal sulfates, alkali metal oxalates, alkali metal borates, alkali metal phosphates, alkali metal halides, alkali metal fluoroborates, alkali metal metaborates, and alkali metal oxides, alkali metal hydroxides, and Yttrium fluoride, yttrium nitrate, yttrium oxide, lanthanum fluoride, lanthanum nitrate, lanthanum oxide, scandium fluoride, scandium nitrate, scandium oxide, boron oxide, boric acid, phosphoric acid, lead oxide, lead fluoride, molybdenum oxide, bismuth oxide.

The fluorine-containing rare-earth borate compounds single-phase polycrystalline powder are prepared by a solid-state method, including the following steps: mixing a A-containing compound (A=Rb, Cs, NH₄), a RE-containing compound (RE=Sc, Y, La), a boron-containing compound, a fluorine-containing compound by a solid-state method to obtain fluorine-containing rare-earth borate compounds. The element A=Rb, Cs, NH₄ in the A-containing compound, element RE=Sc, Y, La in the RE-containing compound, element boron in the boron-containing compound, and element fluorine in the fluorine-containing compound are in a molar ratio of 1.5-2.2:0.8-1.5:2.5-3.5:1.5-2.2, and the raw materials of a A-containing compound (A=Rb, Cs, NH₄), a RE-containing compound (RE=Sc, Y, La), a boron-containing compound, a fluorine-containing compound are mixed uniformly. After grinding, the mixture was preheated to remove moisture and gas, and then cool to room temperature. Further, the mixture was gradually heated to 350-1000° C., held at this temperature for a period of time. The fluorine-containing rare-earth borate compounds single-phase polycrystalline powder are obtained.

b. Preparation of fluorine-containing rare-earth borates seed crystals: the mixture obtained in step a. is slowly cooled to room temperature, and spontaneously crystallized to obtain fluorine-containing rare-earth borate seeds;

c. A seed crystal of A₂REB₃O₆F₂ (A=Rb, Cs, NH₄; RE=Sc, Y, La) was attached with Pt wire to a Pt rod. After being preheated above the solution surface, the seed was introduced into the melt, and held at this temperature for a period of time, the temperature of the furnace was lowered quickly to the initial crystallization temperature.

d. Continue to cool down slowly, and rotate the seed crystal rod to grow the crystal. When the growth was completed, the crystal was drawn out of the melt surface, and the temperature dropped to room temperature, and then obtain the fluorine-containing rare-earth borate nonlinear optical crystals.

The hydrothermal method is used to prepare nonlinear optical crystals A₂REB₃O₆F₂ (A=Rb, Cs, NH₄; RE=Sc, Y, La) comprising the following steps: a. A mixture of a A-containing compound (A=Rb, Cs, NH₄), a RE-containing compound (RE=Sc, Y, La), a boron-containing compound, a fluorine-containing compound were combined with deionized water (0.1-50 mL) or the mineralizers (0.1-50 g), in which element A=Rb, Cs, NH₄ in the A-containing compound, element RE=Sc, Y, La in the RE-containing compound, element boron in the boron-containing compound, element fluorine in the fluorine-containing compound and the mineralizers are in a molar ratio of 1.5-2.2:0.8-1.5:2.5-3.5:1.5-2.2:0-30; the mineralizers include at least one or more AOH, A₂O, AF, ACl, ABr, ABF₄, A₃PO₄, A₃BO₃, ANO₃, A₂C₂O₄, A₂CO₃, AHCO₃, A₂SO₄, RE(NO₃)₃·6H₂O, B₂O₃ KBF₄, NaBF₄, KPF₆ and NH₄PF₆, where A=Rb, Cs, NH₄; RE=Sc, Y, La.

b. The mixture was loaded into the Teflon-lined autoclave and subsequently sealed;

c. The autoclave was heated to 120-330° C., held at this temperature for a period of time, and then cooled to room temperature;

d. Open the autoclave and filter the solution containing crystals to obtain transparent fluorine-containing rare-earth borate nonlinear optical crystals.

The solution method is used to prepare A₂REB₃O₆F₂ (A=Rb, Cs, NH₄; RE=Sc, Y, La) nonlinear optical crystals, comprising the following steps: A mixture of a A-containing compound (A=Rb, Cs, NH₄), a RE-containing compound (RE=Sc, Y, La), a boron-containing compound, a fluorine-containing compound, the cosolvents and deionized water (0.1-400 mL) were placed in a beaker and stirred until dissolved completely, wherein element A=Rb, Cs, NH₄ in the A-containing compound, element RE=Sc, Y, La in the RE-containing compound, element boron in the boron-containing compound, and element fluorine in the fluorine-containing compound and the cosolvents are in a molar ratio of 1.5-2.2:0.8-1.5:2.5-3.5:1.5-2.2:0-20. The cosolvents include at least one or more AOH, A₂O, AF, ACl, ABr, ABF₄, A₃PO₄, A₃BO₃, ANO₃, A₂C₂O₄, A₂CO₃, AHCO₃, A₂SO₄, RE(NO₃)₃·6H₂O, B₂O₃ KBF₄, NaBF₄, KPF₆ and NH₄PF₆, where A=Rb, Cs, NH₄; RE=Sc, Y, La. Then put the beaker on the heating table and heat it to 25° C. After a period of time, the series of fluorine-containing rare-earth borate nonlinear optical crystals are obtained. In order to further grow them, the seed crystals of the series of nonlinear optical crystals were suspended in solution with fine platinum wires. In order to reduce the evaporation of water, the beaker is covered with a layer of polyethylene plate and pierced with dozens of millimeter sized holes. After a period of time, take out the centimeter size fluorine-containing rare-earth borate nonlinear optical crystals from the solution.

The fluorine-containing rare-earth borate compounds provided by the present invention have a chemical formula of A₂REB₃O₆F₂ (A=Rb, Cs, NH₄; RE=Sc, Y, La), which are namely Rb₂ScB₃O₆F₂, Cs₂ScB₃O₆F₂, (NH₄)₂ScB₃O₆F₂, Rb₂YB₃O₆F₂, Cs₂YB₃O₆F₂, (NH₄)₂YB₃O₆F₂, Rb₂LaB₃O₆F₂, Cs₂LaB₃O₆F₂, (NH₄)₂LaB₃O₆F₂ and the formula weights are 247.46-571.14. The series of fluorine-containing rare-earth borate compounds can be prepared by a high-temperature solid-state reaction method, a hydrothermal method, or a solution method based on the following chemical reaction formulas:

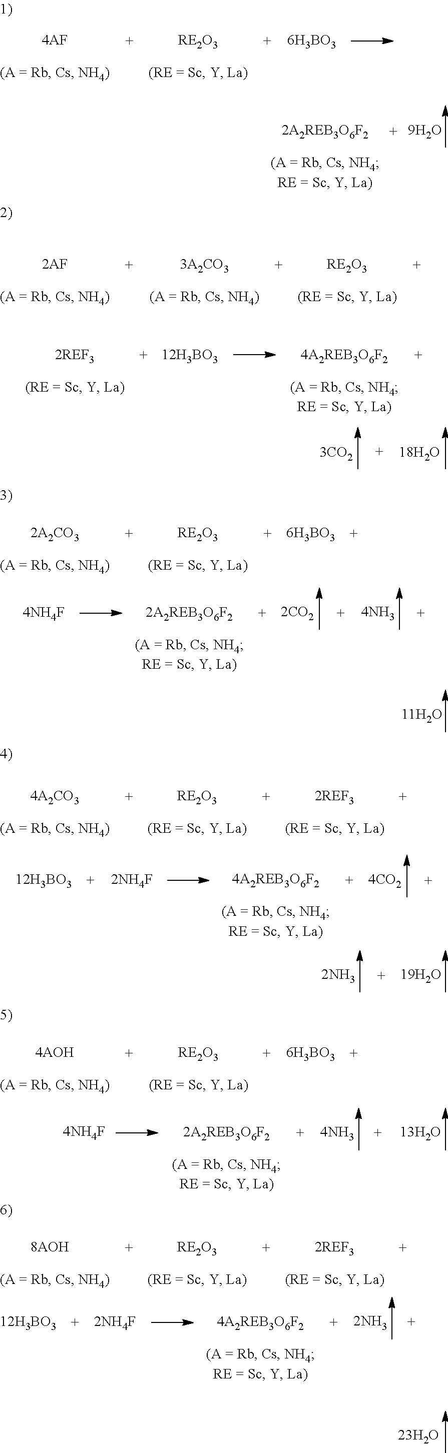

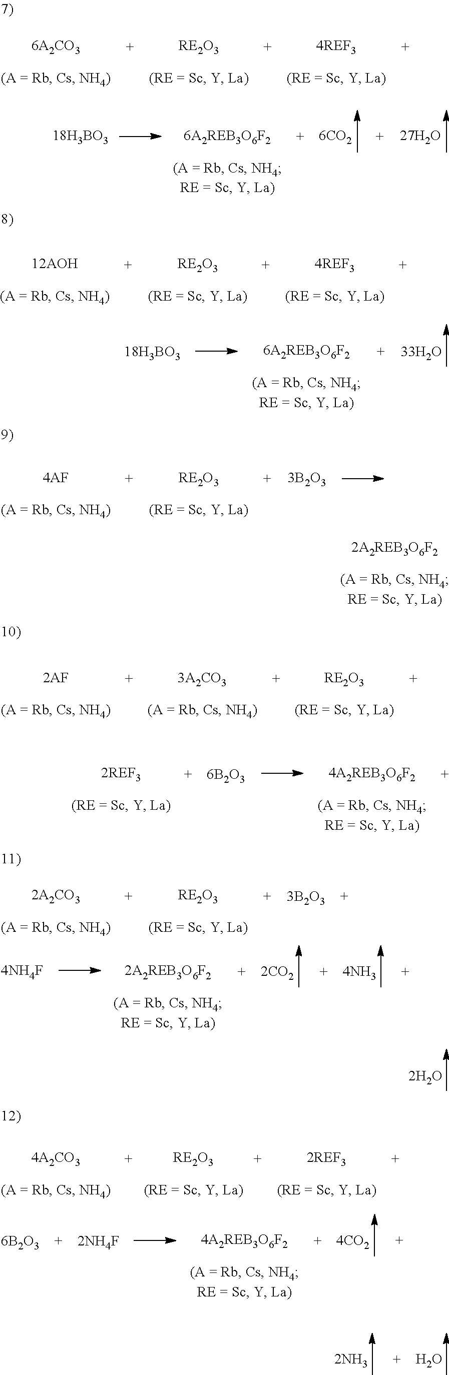

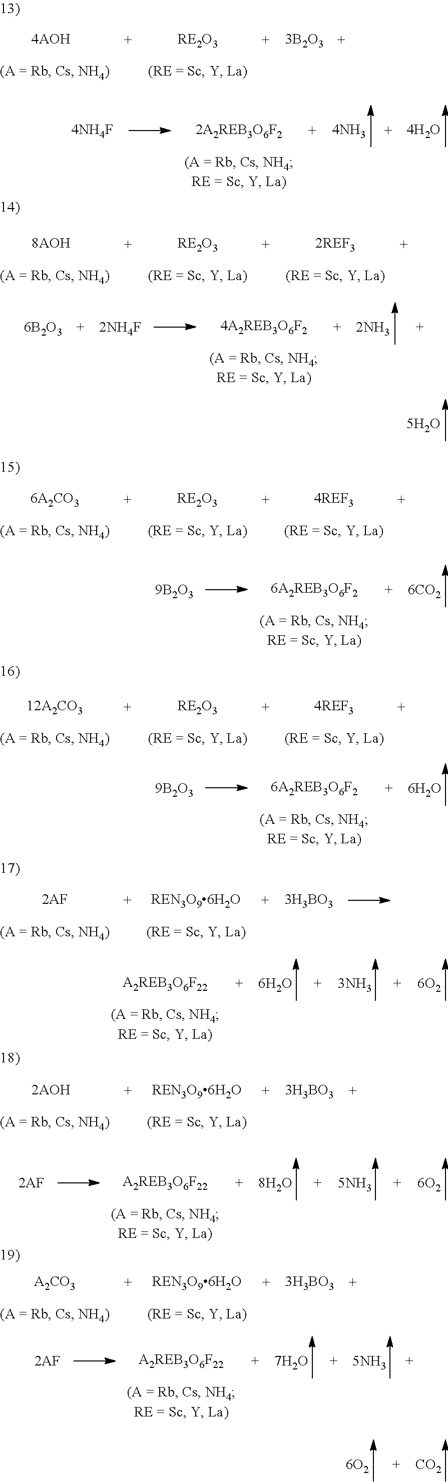

The fluorine-containing rare-earth borate nonlinear optical crystals provided by the present invention are characterized in that the crystals have a chemical formula of A₂REB₃O₆F₂ (A=Rb, Cs, NH₄; RE=Sc, Y, La), and belong to orthorhombic crystal system, as well as have a space group of Amm2, crystal cell parameters of a=2.7182(4)−4.9617(8)Å, b=7.7013(5)−9.9742(6)Å, c=10.2634(1)−12.904(3)Å, Z=2.

The fluorine-containing rare-earth borate nonlinear optical crystals provided by the present invention adopt a high-temperature solution method, a hydrothermal method or a solution method based on the following specific operation steps:

The high-temperature solution method is used to prepare A₂REB₃O₆F₂ (A=Rb, Cs, NH₄; RE=Sc, Y, La) nonlinear optical crystals, comprising the following steps:

a. Uniformly mixed the fluorine-containing rare-earth borate compounds single-phase polycrystalline powder with the fluxing agents, and heated it to a temperature of 400-1000° C., and kept it at a constant temperature for a period of time to obtain a mixed melt, and then cooled to 300-900° C., in which the molar ratios of the fluorine-containing rare-earth borate compounds single-phase polycrystalline powder to the fluxing agents are 1:0-50.

Or directly heat the mixture of a A-containing compound (A=Rb, Cs, NH₄), a RE-containing compound (RE=Sc, Y, La), a boron-containing compound, a fluorine-containing compound or the mixture of a A-containing compound (A=Rb, Cs, NH₄), a RE-containing compound (RE=Sc, Y, La), a boron-containing compound, a fluorine-containing compound and the fluxing agents to 400-1000° C., and held at this temperature for a period of time to obtain a mixed melt. And then cooled to a temperature of 300-900° C., in which the molar ratios of a A-containing compound (A=Rb, Cs, NH₄), a RE-containing compound (RE=Sc, Y, La), a boron-containing compound, a fluorine-containing compound and the fluxing agents are 1.5-2.2:0.8-1.5:2.5-3.5:1.5-2.2:0-50.

The A-containing compounds (A=Rb, Cs, NH₄) include at least one or more of AOH, A₂O and alkali metal salt; alkali metal salt includes at least one or more of AF, ACl, ABr, ANO₃, A₂C₂O₄, A₂CO₃, AHCO₃, A₂SO₄, wherein A=Rb, Cs, NH₄;

The RE-containing compounds (RE=Sc, Y, La) include at least one or more of RE₂O₃, REF₃, RE(NO₃)₃·6H₂O;

The boron-containing compounds include at least one or more of B₂O₃, H₃BO₃ and boron salt; the boron salt includes at least one or more of ABO₂, ABO₃, A₃BO₃, A₂B₄O₇, wherein A=Rb, Cs, NH₄;

The fluorine-containing compounds include at least one or more of AF, REF₃, wherein A=Rb, Cs, NH₄; RE=Sc, Y, La, and other fluorine-containing compounds include at least one or more of KBF₄, NaBF₄, KPF₆ and NH₄PF₆.

The fluxing agents mainly include at least one or more of alkali metal salts, i.e., alkali metal carbonates, alkali metal nitrates, alkali metal sulfates, alkali metal oxalates, alkali metal borates, alkali metal phosphates, alkali metal halides, alkali metal fluoroborates, alkali metal metaborates, and alkali metal oxides, alkali metal hydroxides, and Yttrium fluoride, yttrium nitrate, yttrium oxide, lanthanum fluoride, lanthanum nitrate, lanthanum oxide, scandium fluoride, scandium nitrate, scandium oxide, boron oxide, boric acid, phosphoric acid, lead oxide, lead fluoride, molybdenum oxide, bismuth oxide.

The fluorine-containing rare-earth borate compounds single-phase polycrystalline powder are prepared by a solid-state method, including the following steps: mixing a A-containing compound (A=Rb, Cs, NH₄), a RE-containing compound (RE=Sc, Y, La), a boron-containing compound, a fluorine-containing compound by a solid-state method to obtain the fluorine-containing rare-earth borate compounds. The element A=Rb, Cs, NH₄ in the A-containing compound, element RE=Sc, Y, La in the RE-containing compound, element boron in the boron-containing compound, and element fluorine in the fluorine-containing compound are in a molar ratio of 1.5-2.2:0.8-1.5:2.5-3.5:1.5-2.2, and the raw materials of a A-containing compound (A=Rb, Cs, NH₄), a RE-containing compound (RE=Sc, Y, La), a boron-containing compound, a fluorine-containing compound are mixed uniformly. After grinding, the mixture was preheated to remove moisture and gas, and then cool to room temperature. Further, the mixture was gradually heated to 350-1000° C., held at this temperature for a period of time. The fluorine-containing rare-earth borate compounds single-phase polycrystalline powders are obtained.

b. Preparation of fluorine-containing rare-earth borates seed crystals: the mixture obtained in step a. is slowly cooled to room temperature, and spontaneously crystallized to obtain fluorine-containing rare-earth borate seeds;

c. A seed crystal of A₂REB₃O₆F₂ (A=Rb, Cs, NH₄; RE=Sc, Y, La) was attached with Pt wire to a Pt rod. After being preheated above the solution surface, the seed was introduced into the melt, and held at this temperature for a period of time, the temperature of the furnace was lowered quickly to the initial crystallization temperature.

d. Continue to cool down slowly, and rotate the seed crystal rod to grow the crystal. When the growth was completed, the crystal was drawn out of the melt surface, and the temperature dropped to room temperature, and then obtain the fluorine-containing rare-earth borate nonlinear optical crystals.

The hydrothermal method is used to prepare A₂REB₃O₆F₂ (A=Rb, Cs, NH₄; RE=Sc, Y, La) nonlinear optical crystals, comprising the following steps:

a. The mixture of a A-containing compound (A=Rb, Cs, NH₄), a RE-containing compound (RE=Sc, Y, La), a boron-containing compound, a fluorine-containing compound were combined with deionized water (0.1-50 mL) or the mineralizers (0.1-50 g), in which element A=Rb, Cs, NH₄ in the A-containing compound, element RE=Sc, Y, La in the RE-containing compound, element boron in the boron-containing compound, and element fluorine in the fluorine-containing compound are in a molar ratio of 1.5-2.2:0.8-1.5:2.5-3.5:1.5-2.2:0-30; The mineralizers include at least one or more of AOH, A₂O, AF, ACl, ABr, ABF₄, A₃PO₄, A₃BO₃, ANO₃, A₂C₂O₄, A₂CO₃, AHCO₃, A₂SO₄, A₂HPO₄, AH₂PO₄, RE₂O₃, REF₃, RE(NO₃)₃·6H₂O, B₂O₃, KBF₄, NaBF₄, KPF₆, NH₄PF₆, where A=Rb, Cs, NH₄; RE=Sc, Y, La.

b. The mixture was loaded into Teflon-lined autoclave and subsequently sealed;

c. The autoclave was heated to 120-330° C., held at this temperature for a period of time, and then cooled to room temperature;

d. Open the autoclave and filter the solution containing crystals to obtain a transparent fluorine-containing rare-earth borate nonlinear optical crystals.

The solution method is used to prepare A₂REB₃O₆F₂ (A=Rb, Cs, NH₄; RE=Sc, Y, La) nonlinear optical crystals, comprising the following steps:

The mixture of a A-containing compound (A=Rb, Cs, NH₄), a RE-containing compound (RE=Sc, Y, La), a boron-containing compound, a fluorine-containing compound, the cosolvents and deionized water (0.1-400 mL) were placed in a beaker and stirred until dissolved completely, in which element A=Rb, Cs, NH₄ in the A-containing compound, element RE=Sc, Y, La in the RE-containing compound, element boron in the boron-containing compound, element fluorine in the fluorine-containing compound and the cosolvents are in a molar ratio of 1.5-2.2:0.8-1.5:2.5-3.5:1.5-2.2:0-20. The cosolvents include at least one or more of AOH, A₂O, AF, ACl, ABr, ABF₄, A₃PO₄, A₃BO₃, ANO₃, A₂C₂O₄, A₂CO₃, AHCO₃, A₂SO₄, A₂HPO₄, AH₂PO₄, RE(NO₃)₃·6H₂O, B₂O₃, KBF₄, NaBF₄, KPF₆, NH₄PF₆, where A=Rb, Cs, NH₄; RE=Sc, Y, La. Then put the beaker on the heating table and heat it to 25° C. After a period of time, the series of fluorine-containing rare-earth borate nonlinear optical crystals are obtained. In order to further grow them, the seed crystals of the series of crystals were suspended in solution with fine platinum wires. In order to reduce the evaporation of water, the beaker is covered with a layer of polyethylene plate and pierced with dozens of millimeter sized holes. After a period of time, take out a centimeter size fluorine-containing rare-earth borate nonlinear optical crystals from the solution.

The fluorine-containing rare-earth borates crystals have the advantages of high purity, easy crystal growth, transparent and no package, fast growth speed, low cost and easy to obtain large-size crystals; the obtained crystals have the advantages of wide light transmission band, high hardness, good mechanical properties, not easy to break and deliquescence, and easy to process and preserve. The nonlinear optical device made of the series of fluorine-containing rare-earth borate nonlinear optical crystals obtained by the method of the invention in manufacturing a nonlinear optical device comprising means for generating at least one output radiation with a frequency different from that of the incident electromagnetic radiation after passing at least one beam of incident electromagnetic radiation through at least one nonlinear optical crystal, wherein the nonlinear optical crystal is A₂REB₃O₆F₂, in which A=Rb, Cs, NH₄; RE=Sc, Y, La, and the molecular formula are Rb₂ScB₃O₆F₂, Cs₂ScB₃O₆F₂, (NH₄)₂ScB₃O₆F₂, Rb₂YB₃O₆F₂, Cs₂YB₃O₆F₂, (NH₄)₂YB₃O₆F₂, Rb₂LaB₃O₆F₂, Cs₂LaB₃O₆F₂ and (NH₄)₂LaB₃O₆F₂, respectively.

### BRIEF DESCRIPTION OF THE FIGURES

FIG. 1 is an X-ray powder diffraction pattern of a compound Rb₂YB₃O₆F₂ of the present invention;

FIG. 2 is an X-ray powder diffraction pattern of a compound Cs₂YB₃O₆F₂ of the present invention;

FIG. 3 is a structural diagram of a A₂REB₃O₆F₂ (A=Rb, Cs, NH₄; RE=Sc, Y, La) crystal of the present invention;

FIG. 4 is a working schematic diagram of a nonlinear optical apparatus manufactured from A₂REB₃O₆F₂ (A=Rb, Cs, NH₄; RE=Sc, Y, La) crystal of the present invention, where 1 is the laser generator, 2 is the incident laser beam, 3 is post-treated and optically fabricated A₂REB₃O₆F₂ (A=Rb, Cs, NH₄; RE=Sc, Y, La) NLO devices, 4 is an output beam and 5 is a filter.

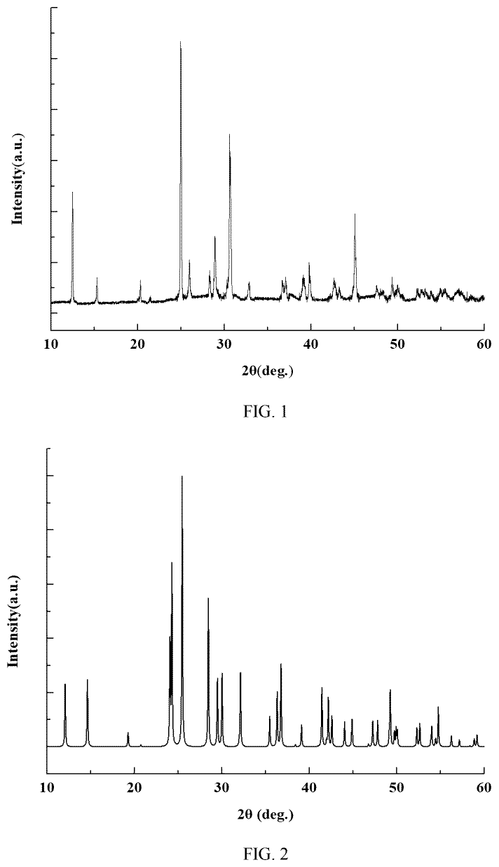

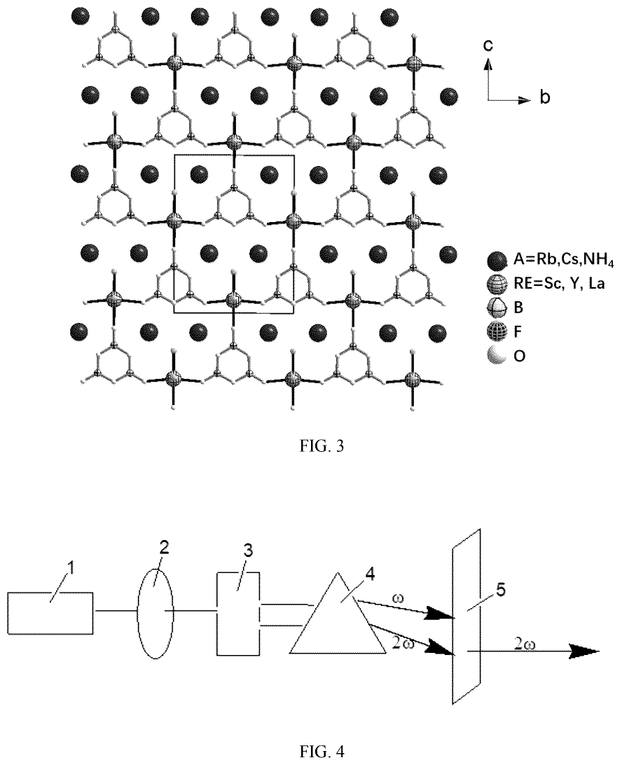

### DETAILED DESCRIPTION OF THE PREFERRED EMBODIMENTS

The present invention is described in detail in combination with the attached drawings and specific embodiments, but the invention is not limited to these embodiments. Any improvement and change made on the basis of the invention shall be within the scope of protection of the invention.

### Embodiment 1

Rb₂YB₃O₆F₂ polycrystalline powder was prepared according to a reaction formula: 4RbF+Y₂O₃+6H₃BO₃→2Rb₂YB₃O₆F₂+9H₂O↑ as follows:

Reagents were weighed according to stoichiometric proportion and were put in a mortar, and then mixed and ground carefully. The mixture was put in a lidless corundum crucible of size of Φ100 mm×100 mm. The said crucible was put into a muffle furnace, heated to 400° C. slowly and held at this temperature for 24 hours. After being cooled down, the loose and porous sample was taken out of the crucible and was once again mixed thoroughly, ground and put back to the crucible and compacted. The mixture was heated at 600° C. for 24 h and cooled to room temperature. The sample was then taken out and ground thoroughly, and the mixture was put back to the crucible and heated at 600° C. for 48 h. The product was analyzed by the powder X-ray diffraction of the product, where the X-ray diffraction pattern was consistent with a theoretical X-ray diffraction pattern of Rb₂YB₃O₆F₂ analyzed by a single-crystal structure.

Then, the single-phase polycrystalline powder was put into a Φ80 mm×80 mm lidless platinum crucible which was placed in the center of a vertical, programmable temperature furnace, was heated at 1000° C. until the melt became transparent and clear, held at this temperature for 3 h, and then quickly cooled to the initial crystallization temperature (900° C.). Then, a platinum wire was promptly dipped into the solution. The temperature was decreased at a rate of 0.5° C./h, then the platinum wire was pulled out of the solution, and allowed to cool to room temperature at a rate of 10° C./h.

Thus, a few colorless, transparent plate crystals crystallized on the platinum wire. The obtained crystals could be used as seeds. A seed crystal of Rb₂YB₃O₆F₂ was attached with Pt wire to a Pt rod and then suspended on solution at 900° C. for a quarter. The seed crystal was kept at this temperature in solution for half an hour while rotating at a rate of 10 rpm. The temperature of the furnace was first lowered quickly to 870° C. and then lowered at a rate of 0.1° C./day. After the growth of crystal ended, the crystal was lifted out of liquid surface. The temperature of the crystal was then lowered to room temperature at a rate of 10° C./h. As a result, transparent Rb₂YB₃O₆F₂ crystal with a size of 20 mm×18 mm×10 mm was obtained.

### Embodiment 2

Rb₂ScB₃O₆F₂ polycrystalline powder was prepared according to a reaction formula: 2RbF+3Rb₂CO₃+Sc₂O₃+2ScF₃+12H₃BO₃→4Rb₂ScB₃O₆F₂+3CO₂↑+18H₂O↑ as follows:

Reagents were weighed according to stoichiometric proportion, preparation of Rb₂ScB₃O₆F₂ crystal by fluxing agent method: LiBO₂—RbF—H₃BO₃ as the fluxing agent systems, the said reagents are used as the solute with the molar ratio of solute:fluxing agents=1:15, the molar ratio of LiBO₂/RbF/H₃BO₃ was selected at 2/5/8. Then, mixed the said reagents with the fluxing agents and put into a Φ80 mm×80 mm lidless platinum crucible which was placed in the center of a vertical, programmable temperature furnace, was heated at 900° C., held at this temperature for 60 h, and then quickly cooled to the initial crystallization temperature (850° C.).

The temperature was decreased to room temperature at a rate of 1.5° C./h to obtain the seeds.

A seed crystal of Rb₂ScB₃O₆F₂ was attached with Pt wire to a Pt rod and then suspended on solution at 850° C. for ten minutes. The seed crystal was kept at this temperature in solution for half an hour while rotating at a rate of 10 rpm. The temperature of the furnace was first lowered quickly to 830° C. and then lowered at a rate of 1° C./day. After the growth of crystal ended, the crystal was lifted out of liquid surface. The temperature of the crystal was then lowered to room temperature at a rate of 20° C./h. As a result, transparent Rb₂ScB₃O₆F₂ crystal with a size of 25 mm×22 mm×12 mm was obtained.

### Embodiment 3

Rb₂YB₃O₆F₂ polycrystalline powder was prepared according to a reaction formula: 2Rb₂CO₃+Y₂O₃+6H₃BO₃+4NH₄F→2Rb₂YB₃O₆F₂+2CO₂↑+4NH₃↑+11H₂O↑ as follows:

The said polycrystalline Rb₂YB₃O₆F₂ is used as the solute with the molar ratio of solute:fluxing agents=1:50, the molar ratio of the fluxing agents K₂CO₃:RbF:H₃BO₃=10:15:25. Then, mixed homogeneously and put into a Φ80 mm×80 mm lidless platinum crucible which was placed in the center of a vertical, programmable temperature furnace, was heated at 400° C. until the melt became transparent and clear, held at this temperature for 60 h, and then quickly cooled to the initial crystallization temperature (350° C.).

The temperature was decreased to room temperature at a rate of 3.5° C./h to obtain the seeds.

A seed crystal of Rb₂YB₃O₆F₂ was attached with Pt wire to a Pt rod and then suspended on solution for 15 minutes. The seed crystal was kept at this temperature in solution for twenty minutes while rotating at a rate of 10 rpm. The temperature of the furnace was first lowered quickly to 330° C. and then lowered at a rate of 3° C./day. After the growth of crystal ended, the crystal was lifted out of liquid surface. The temperature of the crystal was then lowered to room temperature at a rate of 1° C./h. As a result, transparent Rb₂YB₃O₆F₂ crystal with a size of 25 mm×22 mm×20 mm was obtained.

### Embodiment 4

Cs₂YB₃O₆F₂ polycrystalline powder was prepared according to a reaction formula: 4Cs₂CO₃+Y₂O₃+2YF₃+12H₃BO₃+2NH₄F→4Cs₂YB₃O₆F₂+4CO₂↑+2NH₃↑+19H₂O↑ as follows:

The said polycrystalline Cs₂YB₃O₆F₂ is used as the solute with the molar ratio of solute:fluxing agents=1:40, the molar ratio of the fluxing agents Cs₂CO₃:KF:H₃BO₃=10:10:20. Then, mixed homogeneously and put into a Φ80 mm×80 mm lidless platinum crucible which was placed in the center of a vertical, programmable temperature furnace, was heated at 720° C. until the melt became transparent and clear, held at this temperature for 60 h, and then quickly cooled to the initial crystallization temperature (690° C.).

The temperature was decreased to room temperature at a rate of 3.5° C./h to obtain the seeds.

A seed crystal of Cs₂YB₃O₆F₂ was attached with Pt wire to a Pt rod and then suspended on solution for 15 minutes. The seed crystal was kept at this temperature in solution for twenty minutes while rotating at a rate of 10 rpm. The temperature of the furnace was first lowered quickly to 670° C. and then lowered at a rate of 3° C./day. After the growth of crystal ended, the crystal was lifted out of liquid surface. The temperature of the crystal was then lowered to room temperature at a rate of 1° C./h. As a result, transparent Cs₂YB₃O₆F₂ crystal with a size of 25 mm×22 mm×20 mm was obtained.

### Embodiment 5

Rb₂YB₃O₆F₂ polycrystalline powder was prepared according to a reaction formula: 4RbOH+Y₂O₃+6H₃BO₃+4NH₄F→2Rb₂YB₃O₆F₂+4NH₃↑+13H₂O↑ as follows:

Reagents were weighed according to stoichiometric proportion, preparation of Rb₂YB₃O₆F₂ crystal by fluxing agent method: Na₂CO₃—KF—H₃BO₃ as the fluxing agent systems, the said reagents are used as the solute with the molar ratio of solute:fluxing agents=1:18, the molar ratio of Na₂CO₃/KF/H₃BO₃ was selected at 2/6/10. Then, mixed the said reagents with the fluxing agents and put into a ≮80 mm×80 mm lidless platinum crucible which was placed in the center of a vertical, programmable temperature furnace, was heated at 900° C., held at this temperature for 60 h, and then quickly cooled to the initial crystallization temperature (850° C.).

The temperature was decreased to room temperature at a rate of 1.5° C./h to obtain the seeds.

A seed crystal of Rb₂YB₃O₆F₂ was attached with Pt wire to a Pt rod and then suspended on solution at 850° C. for ten minutes. The seed crystal was kept at this temperature in solution for half an hour while rotating at a rate of 10 rpm. The temperature of the furnace was first lowered quickly to 830° C. and then lowered at a rate of 1° C./day. After the growth of crystal ended, the crystal was lifted out of liquid surface. The temperature of the crystal was then lowered to room temperature at a rate of 20° C./h. As a result, transparent Rb₂YB₃O₆F₂ crystal with a size of 25 mm×22 mm×20 mm was obtained.

### Embodiment 6

(NH₄)₂LaB₃O₆F₂ polycrystalline powder was prepared according to a reaction formula: 8(NH₄)OH+La₂O₃+2LaF₃+12H₃BO₃+2NH₄F→4(NH₄)₂LaB₃O₆F₂+2NH₃↑+23H₂O↑ as follows:

Reagents were weighed according to stoichiometric proportion and mix it with the cosolvents, in which the molar ratio of the cosolvents H₃BO₃ and La(NO₃)₃·6H₂O was 14:6, then the mixture was placed in a beaker (10 mL), further add 0.1 mL deionized water into the beaker and stirred until dissolved completely. Then put the beaker on the heating table and heat it to 25° C. After 2 days, (NH₄)₂LaB₃O₆F₂ nonlinear optical crystals are obtained. In order to further grow them, the seed crystals of (NH₄)₂LaB₃O₆F₂ were suspended in solution with fine platinum wires. In order to reduce the evaporation of water, the beaker is covered with a layer of polyethylene plate and pierced with dozens of millimeter sized holes. After 3 weeks, take out a centimeter size (NH₄)₂LaB₃O₆F₂ nonlinear optical crystals from the solution.

### Embodiment 7

Cs₂YB₃O₆F₂ polycrystalline powder was prepared according to a reaction formula: 6Cs₂CO₃+Y₂O₃+4YF₃+18H₃BO₃→6Cs₂YB₃O₆F₂+6CO₂↑+27H₂O↑ as follows:

The said polycrystalline Cs₂YB₃O₆F₂ is used as the solute with the molar ratio of solute:fluxing agents=1:35, the molar ratio of fluxing agents KF:Cs₂CO₃:H₃BO₃=8:7:20. Then, mixed homogeneously and put into a Φ80 mm×80 mm lidless platinum crucible which was placed in the center of a vertical, programmable temperature furnace, was heated at 880° C. until the melt became transparent and clear, held at this temperature for 60 h, and then quickly cooled to the initial crystallization temperature (840° C.).

The temperature was decreased to room temperature at a rate of 3.5° C./h to obtain the seeds.

A seed crystal of Cs₂YB₃O₆F₂ was attached with Pt wire to a Pt rod and then suspended on solution for 15 minutes. The seed crystal was kept at this temperature in solution for twenty minutes while rotating at a rate of 10 rpm. The temperature of the furnace was first lowered quickly to 830° C. and then lowered at a rate of 3° C./day. After the growth of crystal ended, the crystal was lifted out of liquid surface. The temperature of the crystal was then lowered to room temperature at a rate of 1° C./h. As a result, transparent Cs₂YB₃O₆F₂ crystal with a size of 20 mm×15 mm×6 mm was obtained.

### Embodiment 8

Cs₂YB₃O₆F₂ polycrystalline powder was prepared according to a reaction formula: 12CsOH+Y₂O₃+4YF₃+18H₃BO₃→6Cs₂YB₃O₆F₂+33H₂O↑ as follows:

Reagents were weighed according to stoichiometric proportion, preparation of Cs₂YB₃O₆F₂ crystal by fluxing agent method: CsF—H₃BO₃ as the fluxing agent systems, the said reagents are used as the solute with the molar ratio of solute:fluxing agents=1:27, the molar ratio of CsF/H₃BO₃ was selected at 12/15. Then, mixed the said reagents with the fluxing agents and put into a Φ80 mm×80 mm lidless platinum crucible which was placed in the center of a vertical, programmable temperature furnace, was heated at 860° C., held at this temperature for 60 h, and then quickly cooled to the initial crystallization temperature (830° C.).

The temperature was decreased to room temperature at a rate of 3.5° C./h to obtain the seeds.

A seed crystal of Cs₂YB₃O₆F₂ was attached with Pt wire to a Pt rod and then suspended on solution at 830° C. for 15 minutes. The seed crystal was kept at this temperature in solution for half an hour while rotating at a rate of 10 rpm. The temperature of the furnace was first lowered quickly to 820° C. and then lowered at a rate of 3° C./day. After the growth of crystal ended, the crystal was lifted out of liquid surface. The temperature of the crystal was then lowered to room temperature at a rate of 1° C./h. As a result, transparent Cs₂YB₃O₆F₂ crystal with a size of 20 mm×15 mm×6 mm was obtained.

### Embodiment 9

Rb₂LaB₃O₆F₂ polycrystalline powder was prepared according to a reaction formula: 4RbF+La₂O₃+3B₂O₃→2Rb₂LaB₃O₆F₂ as follows:

Reagents were weighed according to stoichiometric proportion, preparation of Rb₂LaB₃O₆F₂ crystal by fluxing agent method: RbOH—H₃BO₃ as the fluxing agent systems, the said reagents are used as the solute with the molar ratio of solute:fluxing agents=1:30, the molar ratio of RbOH/H₃BO₃ was selected at 10/20. Then, mixed the said reagents with the fluxing agents and put into a Φ80 mm×80 mm lidless platinum crucible which was placed in the center of a vertical, programmable temperature furnace, was heated at 800° C., held at this temperature for 60 h, and then quickly cooled to the initial crystallization temperature (770° C.).

The temperature was decreased to room temperature at a rate of 3.5° C./h to obtain the seeds.

A seed crystal of Rb₂LaB₃O₆F₂ was attached with Pt wire to a Pt rod and then suspended on solution at 770° C. for 15 minutes. The seed crystal was kept at this temperature in solution for half an hour while rotating at a rate of 10 rpm. The temperature of the furnace was first lowered quickly to 750° C. and then lowered at a rate of 3° C./day. After the growth of crystal ended, the crystal was lifted out of liquid surface. The temperature of the crystal was then lowered to room temperature at a rate of 1° C./h. As a result, transparent Rb₂LaB₃O₆F₂ crystal with a size of 22 mm×20 mm×10 mm was obtained.

### Embodiment 10

Cs₂YB₃O₆F₂ polycrystalline powder was prepared according to a reaction formula: 2CsF+3Cs₂CO₃+Y₂O₃+2YF₃+6B₂O₃→4Cs₂YB₃O₆F₂+3CO₂↑ as follows:

Reagents were weighed according to stoichiometric proportion, preparation of Cs₂YB₃O₆F₂ crystal by fluxing agent method: CsF—Cs₂CO₃—H₃BO₃ as the fluxing agent systems, the said reagents are used as the solute with the molar ratio of solute:fluxing agents=1:50, the molar ratio of CsF/Cs₂CO₃/H₃BO₃ was selected at 17/17/32. Then, mixed the said reagents with the fluxing agents and put into a Φ80 mm×80 mm lidless platinum crucible which was placed in the center of a vertical, programmable temperature furnace, was heated at 600° C., held at this temperature for 60 h, and then quickly cooled to the initial crystallization temperature (570° C.).

The temperature was decreased to room temperature at a rate of 3.5° C./h to obtain the seeds.

A seed crystal of Cs₂YB₃O₆F₂ was attached with Pt wire to a Pt rod and then suspended on solution at 570° C. for 15 minutes. The seed crystal was kept at this temperature in solution for half an hour while rotating at a rate of 10 rpm. The temperature of the furnace was first lowered quickly to 550° C. and then lowered at a rate of 3° C./day. After the growth of crystal ended, the crystal was lifted out of liquid surface. The temperature of the crystal was then lowered to room temperature at a rate of 1° C./h. As a result, transparent Cs₂YB₃O₆F₂ crystal with a size of 13 mm×10 mm×7 mm was obtained.

### Embodiment 11

Rb₂YB₃O₆F₂ polycrystalline powder was prepared according to a reaction formula: 2Rb₂CO₃+Y₂O₃+3B₂O₃+4NH₄F→2Rb₂YB₃O₆F₂+2CO₂↑+4NH₃↑+2H₂O↑ as follows:

Reagents were weighed according to stoichiometric proportion, preparation of Rb₂YB₃O₆F₂ crystal by fluxing agent method: RbF—RbOH—B₂O₃ as the fluxing agent systems, the said reagents are used as the solute with the molar ratio of solute:fluxing agents=1:45, the molar ratio of RbF/RbOH/B₂O₃ was selected at 15/15/15. Then, mixed the said reagents with the fluxing agents and put into a Φ80 mm×80 mm lidless platinum crucible which was placed in the center of a vertical, programmable temperature furnace, was heated at 700° C., held at this temperature for 60 h, and then quickly cooled to the initial crystallization temperature (670° C.).

The temperature was decreased to room temperature at a rate of 3.5° C./h to obtain the seeds.

A seed crystal of Rb₂YB₃O₆F₂ was attached with Pt wire to a Pt rod and then suspended on solution at 670° C. for 15 minutes. The seed crystal was kept at this temperature in solution for half an hour while rotating at a rate of 10 rpm. The temperature of the furnace was first lowered quickly to 650° C. and then lowered at a rate of 3° C./day. After the growth of crystal ended, the crystal was lifted out of liquid surface. The temperature of the crystal was then lowered to room temperature at a rate of 1° C./h. As a result, transparent Rb₂YB₃O₆F₂ crystal with a size of 13 mm×10 mm×7 mm was obtained.

### Embodiment 12

(NH₄)₂ScB₃O₆F₂ polycrystalline powder was prepared according to a reaction formula: 4(NH₄)₂CO₃+Sc₂O₃+2ScF₃+6B₂O₃+2NH₄F→4(NH₄)₂ScB₃O₆F₂+4CO₂↑+2NH₃↑+H₂O↑ as follows:

a. Reagents were weighed according to stoichiometric proportion and mix it with the mineralizers, in which the molar ratio of H₃BO₃, (NH₄)OH and (NH₄)₂C₂O₄ was 10:10:10, then loaded into a 21 mL Teflon-lined autoclave, further added 0.1 g H₃BO₃ to obtain the mixed liquid.

b. The mixture was loaded into Teflon-lined autoclave and subsequently sealed;

c. The autoclave was heated to 330° C. at a rate of 10° C./h, held at this temperature for 11 days, and then cooled to room temperature at a rate of 4° C./h;

d. Open the autoclave and filter the solution containing crystals to obtain a transparent (NH₄)₂ScB₃O₆F₂ nonlinear optical crystals.

### Embodiment 13

(NH₄)₂YB₃O₆F₂ polycrystalline powder was prepared according to a reaction formula: 4(NH₄)OH+Y₂O₃+3B₂O₃+4NH₄F→2(NH₄)₂YB₃O₆F₂+4NH₃↑+4H₂O↑ as follows:

Reagents were weighed according to stoichiometric proportion, preparation of (NH₄)₂YB₃O₆F₂ crystal by fluxing agent method: (NH₄)₂C₂O₄—B₂O₃—CsF as the fluxing agent systems, the said reagents are used as the solute with the molar ratio of solute:fluxing agents=1:39, the molar ratio of (NH₄)₂C₂O₄/B₂O₃/CsF was selected at 7/7/25. Then, mixed the said reagents with the fluxing agents and put into a Φ80 mm×80 mm lidless platinum crucible which was placed in the center of a vertical, programmable temperature furnace, was heated at 480° C., held at this temperature for 60 h, and then quickly cooled to the initial crystallization temperature (450° C.).

The temperature was decreased to room temperature at a rate of 3.5° C./h to obtain the seeds.

A seed crystal of (NH₄)₂YB₃O₆F₂ was attached with Pt wire to a Pt rod and then suspended on solution at 450° C. for 15 minutes. The seed crystal was kept at this temperature in solution for half an hour while rotating at a rate of 10 rpm. The temperature of the furnace was first lowered quickly to 430° C. and then lowered at a rate of 3° C./day. After the growth of crystal ended, the crystal was lifted out of liquid surface. The temperature of the crystal was then lowered to room temperature at a rate of 1° C./h. As a result, transparent (NH₄)₂YB₃O₆F₂ crystal with a size of 13 mm×10 mm×7 mm was obtained.

### Embodiment 14

Cs₂LaB₃O₆F₂ polycrystalline powder was prepared according to a reaction formula: 8CsOH+La₂O₃+2LaF₃+6B₂O₃+2NH₄F→4Cs₂LaB₃O₆F₂+2NH₃↑+5H₂O↑ as follows:

The said polycrystalline Cs₂LaB₃O₆F₂ is used as the solute with the molar ratio of solute:fluxing agents=1:36, the molar ratio of fluxing agents CsF:LaF₃:CsNO₃:B₂O₃=8:5:8:15. Then, mixed homogeneously and put into a Φ80 mm×80 mm lidless platinum crucible which was placed in the center of a vertical, programmable temperature furnace, was heated at 780° C. until the melt became transparent and clear, held at this temperature for 60 h, and then quickly cooled to the initial crystallization temperature (760° C.).

The temperature was decreased to room temperature at a rate of 3.5° C./h to obtain the seeds.

A seed crystal of Cs₂LaB₃O₆F₂ was attached with Pt wire to a Pt rod and then suspended on solution for 15 minutes. The seed crystal was kept at this temperature in solution for twenty minutes while rotating at a rate of 10 rpm. The temperature of the furnace was first lowered quickly to 750° C. and then lowered at a rate of 3° C./day. After the growth of crystal ended, the crystal was lifted out of liquid surface. The temperature of the crystal was then lowered to room temperature at a rate of 1° C./h. As a result, transparent Cs₂LaB₃O₆F₂ crystal with a size of 16 mm×12 mm×10 mm was obtained.

### Embodiment 15

Rb₂LaB₃O₆F₂ polycrystalline powder was prepared according to a reaction formula: 6Rb₂CO₃+La₂O₃+4LaF₃+9B₂O₃→6Rb₂LaB₃O₆F₂+6CO₂↑ as follows:

Reagents were weighed according to stoichiometric proportion, preparation of Rb₂LaB₃O₆F₂ crystal by fluxing agent method: CsF—LaF₃—KOH—B₂O₃ as the fluxing agent systems, the said reagents are used as the solute with the molar ratio of solute:fluxing agents=1:26, the molar ratio of CsF/LaF₃/KOH/B₂O₃ was selected at 10/3/5/8. Then, mixed the said reagents with the fluxing agents and put into a Φ80 mm×80 mm lidless platinum crucible which was placed in the center of a vertical, programmable temperature furnace, was heated at 950° C., held at this temperature for 60 h, and then quickly cooled to the initial crystallization temperature (930° C.).

The temperature was decreased to room temperature at a rate of 3.5° C./h to obtain the seeds.

A seed crystal of Rb₂LaB₃O₆F₂ was attached with Pt wire to a Pt rod and then suspended on solution at 930° C. for 15 minutes. The seed crystal was kept at this temperature in solution for half an hour while rotating at a rate of 10 rpm. The temperature of the furnace was first lowered quickly to 920° C. and then lowered at a rate of 3° C./day. After the growth of crystal ended, the crystal was lifted out of liquid surface. The temperature of the crystal was then lowered to room temperature at a rate of 1° C./h. As a result, transparent Rb₂LaB₃O₆F₂ crystal with a size of 15 mm×10 mm×10 mm was obtained.

### Embodiment 16

Cs₂YB₃O₆F₂ polycrystalline powder was prepared according to a reaction formula: 12CsOH+Y₂O₃+4YF₃+9B₂O₃→6Cs₂YB₃O₆F₂+6H₂O↑ as follows:

Reagents were weighed according to stoichiometric proportion, preparation of Cs₂YB₃O₆F₂ crystal by fluxing agent method: Cs₂CO₃—YF₃—KF—B₂O₃ as the fluxing agent systems, the said reagents are used as the solute with the molar ratio of solute:fluxing agents=1:26, the molar ratio of Cs₂CO₃/YF₃/KF/B₂O₃ was selected at 10/3/5/8. Then, mixed the said reagents with the fluxing agents and put into a Φ80 mm×80 mm lidless platinum crucible which was placed in the center of a vertical, programmable temperature furnace, was heated at 780° C., held at this temperature for 60 h, and then quickly cooled to the initial crystallization temperature (750° C.).

The temperature was decreased to room temperature at a rate of 3.5° C./h to obtain the seeds.

A seed crystal of Cs₂YB₃O₆F₂ was attached with Pt wire to a Pt rod and then suspended on solution at 750° C. for 15 minutes. The seed crystal was kept at this temperature in solution for half an hour while rotating at a rate of 10 rpm. The temperature of the furnace was first lowered quickly to 730° C. and then lowered at a rate of 3° C./day. After the growth of crystal ended, the crystal was lifted out of liquid surface. The temperature of the crystal was then lowered to room temperature at a rate of 1° C./h. As a result, transparent Cs₂YB₃O₆F₂ crystal with a size of 18 mm×15 mm×10 mm was obtained.

### Embodiment 17

Rb₂LaB₃O₆F₂ polycrystalline powder was prepared according to a reaction formula: 2RbF+La(NO₃)₃·6H₂O+3H₃BO₃→Rb₂LaB₃O₆F₂+6H₂O↑+3NH₃↑+6O₂↑ as follows:

Reagents were weighed according to stoichiometric proportion, preparation of Rb₂LaB₃O₆F₂ crystal by fluxing agent method: RbF—H₃BO₃ as the fluxing agent systems, the said reagents are used as the solute with the molar ratio of solute:fluxing agents=1:35, the molar ratio of RbF/H₃BO₃ was selected at 13/22. Then, mixed the said reagents with the fluxing agents and put into a Φ80 mm×80 mm lidless platinum crucible which was placed in the center of a vertical, programmable temperature furnace, was heated at 710° C., held at this temperature for 60 h, and then quickly cooled to the initial crystallization temperature (690° C.).

The temperature was decreased to room temperature at a rate of 3.5° C./h to obtain the seeds.

A seed crystal of Rb₂LaB₃O₆F₂ was attached with Pt wire to a Pt rod and then suspended on solution at 690° C. for 15 minutes. The seed crystal was kept at this temperature in solution for half an hour while rotating at a rate of 10 rpm. The temperature of the furnace was first lowered quickly to 680° C. and then lowered at a rate of 3° C./day. After the growth of crystal ended, the crystal was lifted out of liquid surface. The temperature of the crystal was then lowered to room temperature at a rate of 1° C./h. As a result, transparent Rb₂LaB₃O₆F₂ crystal with a size of 22 mm×18 mm×14 mm was obtained.

### Embodiment 18

(NH₄)₂YB₃O₆F₂ polycrystalline powder was prepared according to a reaction formula: 2(NH₄)OH+Y(NO₃)₃·6H₂O+3H₃BO₃+2NH₄F→(NH₄)₂YB₃O₆F₂+8H₂O↑+5NH₃↑+6O₂↑ as follows:

a. Reagents were weighed according to stoichiometric proportion, and mix it with the mineralizers, in which the molar ratio of H₃BO₃:NH₄OH:(NH₄)₂C₂O₄ was 10:2:10, then loaded into a 21 mL Teflon-lined autoclave, further added 0.1 g H₃BO₃ to obtain the mixed liquid.

b. The mixture was loaded into Teflon-lined autoclave and subsequently sealed;

c. The autoclave was heated to 120° C. at a rate of 10° C./h, held at this temperature for 11 days, and then cooled to room temperature at a rate of 4° C./h;

d. Open the autoclave and filter the solution containing crystals to obtain a transparent (NH₄)₂YB₃O₆F₂ nonlinear optical crystals.

### Embodiment 19

Cs₂ScB₃O₆F₂ polycrystalline powder was prepared according to a reaction formula: Cs₂CO₃+Sc(NO₃)₃·6H₂O+3H₃BO₃+2NH₄F→Cs₂ScB₃O₆F₂+7H₂O↑+5NH₃↑+6O₂↑+CO₂↑ as follows:

The said polycrystalline Cs₂ScB₃O₆F₂ is used as the solute with the molar ratio of solute:fluxing agents=1:33, the molar ratio of fluxing agents LiF:Cs₂CO₃:H₃BO₃=7:8:18. Then, mixed homogeneously and put into a Φ80 mm×80 mm lidless platinum crucible which was placed in the center of a vertical, programmable temperature furnace, was heated at 750° C. until the melt became transparent and clear, held at this temperature for 60 h, and then quickly cooled to the initial crystallization temperature (730° C.).

The temperature was decreased to room temperature at a rate of 3.5° C./h to obtain the seeds.

A seed crystal of Cs₂ScB₃O₆F₂ was attached with Pt wire to a Pt rod and then suspended on solution for 15 minutes. The seed crystal was kept at this temperature in solution for twenty minutes while rotating at a rate of 10 rpm. The temperature of the furnace was first lowered quickly to 720° C. and then lowered at a rate of 3° C./day. After the growth of crystal ended, the crystal was lifted out of liquid surface. The temperature of the crystal was then lowered to room temperature at a rate of 1° C./h. As a result, transparent Cs₂ScB₃O₆F₂ crystal with a size of 22 mm×18 mm×12 mm was obtained.

### Embodiment 20

Any Rb₂ScB₃O₆F₂, Cs₂ScB₃O₆F₂, (NH₄)₂ScB₃O₆F₂, Rb₂YB₃O₆F₂, Cs₂YB₃O₆F₂, (NH₄)₂YB₃O₆F₂, Rb₂LaB₃O₆F₂, Cs₂LaB₃O₆F₂ and (NH₄)₂LaB₃O₆F₂ nonlinear optical crystals obtained according to embodiments 1 to 19 were mounted on the position of 3 as shown in FIG. 4; a Q-switched Nd: YAG laser device was taken as a light source with an incident wavelength of 1064 nm at the room temperature came into Rb₂ScB₃O₆F₂, Cs₂ScB₃O₆F₂, (NH₄)₂ScB₃O₆F₂, Rb₂YB₃O₆F₂, Cs₂YB₃O₆F₂, (NH₄)₂YB₃O₆F₂, Rb₂LaB₃O₆F₂, Cs₂LaB₃O₆F₂ and (NH₄)₂LaB₃O₆F₂ single crystal 3 to generate frequency-doubled laser with a wavelength of 532 nm; and an outgoing beam 4 contained infrared lights with wavelengths of 1064 nm and 532 nm, and frequency-doubled laser with a wavelength of 532 nm was obtained after the light was filtered by a light filter 5.

### Embodiment 21

Any Rb₂ScB₃O₆F₂, Cs₂ScB₃O₆F₂, (NH₄)₂ScB₃O₆F₂, Rb₂YB₃O₆F₂, Cs₂YB₃O₆F₂, (NH₄)₂YB₃O₆F₂, Rb₂LaB₃O₆F₂, Cs₂LaB₃O₆F₂ and (NH₄)₂LaB₃O₆F₂ nonlinear optical crystals obtained according to embodiments 1 to 19 were mounted on the position of 3 as shown in FIG. 4; a Q-switched Nd: YAG laser device was taken as a light source with an incident wavelength of 532 nm at the room temperature came into Rb₂ScB₃O₆F₂, Cs₂ScB₃O₆F₂, (NH₄)₂ScB₃O₆F₂, Rb₂YB₃O₆F₂, Cs₂YB₃O₆F₂, (NH₄)₂YB₃O₆F₂, Rb₂LaB₃O₆F₂, Cs₂LaB₃O₆F₂ and (NH₄)₂LaB₃O₆F₂ single crystal 3 to generate frequency-doubled laser with a wavelength of 266 nm; and an outgoing beam 4 contained infrared lights with wavelengths of 532 nm and 266 nm, and frequency-doubled laser with a wavelength of 266 nm was obtained after the light was filtered by a light filter 5.

### Embodiment 22

Any Rb₂ScB₃O₆F₂, Cs₂ScB₃O₆F₂, (NH₄)₂ScB₃O₆F₂, Rb₂YB₃O₆F₂, Cs₂YB₃O₆F₂, (NH₄)₂YB₃O₆F₂, Rb₂LaB₃O₆F₂, Cs₂LaB₃O₆F₂ and (NH₄)₂LaB₃O₆F₂ nonlinear optical crystals obtained according to embodiments 1 to 19 were subjected to directional cutting and polishing processing to form a single crystal device. A 1064 nm Nd: YAG Q-switched laser source was used as a pump source to generate a laser output with a wavelength shorter than 266 nm.

What is claimed is:

1. The fluorine-containing rare-earth borate nonlinear optical crystals having a chemical formula of A₂REB₃O₆F₂ (A=Rb, Cs, NH₄; RE=Sc, Y, La), i.e. Rb₂ScB₃O₆F₂, Cs₂ScB₃O₆F₂, (NH₄)₂ScB₃O₆F₂, Rb₂YB₃O₆F₂, Cs₂YB₃O₆F₂, (NH₄)₂YB₃O₆F₂, Rb₂LaB₃O₆F₂, Cs₂LaB₃O₆F₂ and (NH₄)₂LaB₃O₆F₂, respectively, which belong to orthorhombic crystal system, and have a space group of Amm2 with unit-cell parameters a=2.7182(4)−4.9617(8)Å, b=7.7013(5)−9.9742(6)Å, c=10.2634(1)−12.904(3)Å, Z=2.

2. A method for synthesizing fluorine-containing rare-earth borate nonlinear optical crystals as claimed in claim 1, the series of fluorine-containing rare-earth borate nonlinear optical crystals were synthesized by a high-temperature solution method, a hydrothermal method, or a solution method.

3. The growth method for the series of fluorine-containing rare-earth borate nonlinear optical crystals as claimed in claim 2, based on the following operation steps:
The high-temperature solution method is used to prepare A₂REB₃O₆F₂ (A=Rb, Cs, NH₄; RE=Sc, Y, La) nonlinear optical crystals, comprising the following steps: A₂REB₃O₆F₂ (A=Rb, Cs, NH₄; RE=Sc, Y, La) compounds or the mixture of the A₂REB₃O₆F₂ (A=Rb, Cs, NH₄; RE=Sc, Y, La) compounds with the fluxing agents is heated to obtain a mixed melt, or directly heat the mixture of a A-containing compound (A=Rb, Cs, NH₄), a RE-containing compound (RE-Sc, Y, La), a boron-containing compound, a fluorine-containing compound or the mixture of a A-containing compound (A=Rb, Cs, NH₄), a RE-containing compound (RE=Sc, Y, La), a boron-containing compound, a fluorine-containing compound and the fluxing agents to obtain a mixed melt; the crucible of the liquid is placed in the crystal growth furnace to cool down the temperature, and then the seed rod is lifted out of the liquid surface before the melt solidifies to obtain the seed crystal; the seed crystal is fixed on the seed rod, and the seed crystal is brought down to the liquid surface of the mixed melt or in the mixed melt for melting back to the saturation temperature; cooling or constant temperature growth; finally, fluorine-containing rare-earth borate A₂REB₃O₆F₂ (A=Rb, Cs, NH₄; RE=Sc, Y, La) nonlinear optical crystals were prepared;
The hydrothermal method is used to prepare A₂REB₃O₆F₂ (A=Rb, Cs, NH₄; RE=Sc, Y, La) nonlinear optical crystals, comprising the following steps: A₂REB₃O₆F₂ (A=Rb, Cs, NH₄; RE=Sc, Y, La) compounds or the mixture of the A₂REB₃O₆F₂ (A=Rb, Cs, NH₄; RE=Sc, Y, La) compounds with the mineralizers to obtain a uniform mixture; or directly mixing a A-containing compound (A=Rb, Cs, NH₄), a RE-containing compound (RE=Sc, Y, La), a boron-containing compound, a fluorine-containing compound or a A-containing compound (A=Rb, Cs, NH₄), a RE-containing compound (RE=Sc, Y, La), a boron-containing compound, a fluorine-containing compound and the mineralizers to obtain a uniform mixture, the mixture was combined with deionized water, and loaded into Teflon-lined autoclave, the autoclave was heated, and then cooled to room temperature; finally, filter the solution containing crystals to obtain the transparent fluorine-containing rare-earth borate A₂REB₃O₆F₂ (A=Rb, Cs, NH₄; RE=Sc, Y, La) nonlinear optical crystals.
The solution method is used to prepare A₂REB₃O₆F₂ (A=Rb, Cs, NH₄; RE=Sc, Y, La) nonlinear optical crystals, comprising the following steps: A₂REB₃O₆F₂ (A=Rb, Cs, NH₄; RE=Sc, Y, La) compounds or the mixture of the A₂REB₃O₆F₂ (A=Rb, Cs, NH₄; RE=Sc, Y, La) compounds with the cosolvents to obtain a uniform mixture; or directly mixing a A-containing compound (A=Rb, Cs, NH₄), a RE-containing compound (RE=Sc, Y, La), a boron-containing compound, a fluorine-containing compound or the mixture of a A-containing compound (A=Rb, Cs, NH₄), a RE-containing compound (RE=Sc, Y, La), a boron-containing compound, a fluorine-containing compound and the cosolvents to obtain a uniform mixture, the mixture was dissolved in deionized water and placed in a beaker stirred until dissolved completely, then put the beaker on the heating table to heat for a period of time, the series of fluorine-containing rare-earth borate nonlinear optical crystals are obtained; in order to further grow them, the seed crystals of the series of crystals were suspended in solution with fine platinum wires, in order to reduce the evaporation of water, the beaker is covered with a layer of polyethylene plate and pierced with dozens of millimeter sized holes; after a period of time, take out a centimeter size fluorine-containing rare-earth borate A₂REB₃O₆F₂ (A=Rb, Cs, NH₄; RE=Sc, Y, La) nonlinear optical crystals from the solution.

4. The crystal growth method according to claim 3, based on the following specific operation steps:
The high-temperature solution method is used to prepare A₂REB₃O₆F₂ (A=Rb, Cs, NH₄; RE=Sc, Y, La) nonlinear optical crystals, the series of fluorine-containing rare-earth borate compounds and the fluxing agents are in a ratio of 1:0-50, or the molar ratio of a A-containing compound (A=Rb, Cs, NH₄), a RE-containing compound (RE=Sc, Y, La), a boron-containing compound, a fluorine-containing compound and the fluxing agents are 1.5-2.2:0.8-1.5:2.5-3.5:1.5-2.2:0-50; The fluxing agents mainly include at least one or more of alkali metal salts, i.e., alkali metal carbonates, alkali metal nitrates, alkali metal sulfates, alkali metal oxalates, alkali metal borates, alkali metal phosphates, alkali metal halides, alkali metal fluoroborates, alkali metal metaborates, and alkali metal oxides, alkali metal hydroxides, and Yttrium fluoride, yttrium nitrate, yttrium oxide, lanthanum fluoride, lanthanum nitrate, lanthanum oxide, scandium fluoride, scandium nitrate, scandium oxide, boron oxide, boric acid, phosphoric acid, lead oxide, lead fluoride, molybdenum oxide, bismuth oxide;
The hydrothermal method is used to prepare A₂REB₃O₆F₂ (A=Rb, Cs, NH₄; RE=Sc, Y, La) nonlinear optical crystals, the series of fluorine-containing rare-earth borate compounds and the mineralizers are in a ratio of 1:0-30; or the molar ratio of a A-containing compound (A=Rb, Cs, NH₄), a RE-containing compound (RE=Sc, Y, La), a boron-containing compound, a fluorine-containing compound and the fluxing agents are 1.5-2.2:0.8-1.5:2.5-3.5:1.5-2.2:0-30; the mineralizers include at least one or more of AOH, A₂O, AF, ACl, ABr, ABF₄, A₃PO₄, A₃BO₃, ANO₃, A₂C₂O₄, A₂CO₃, AHCO₃, A₂SO₄, A₂HPO₄, AH₂PO₄, RE(NO₃)₃·6H₂O, B₂O₃, wherein A=Rb, Cs, NH₄; RE=Sc, Y, La;
The solution method is used to prepare A₂REB₃O₆F₂ (A=Rb, Cs, NH₄; RE=Sc, Y, La) nonlinear optical crystals, the series of fluorine-containing rare-earth borate compounds and the cosolvents are in a ratio of 1:0-20; or a molar ratio of a A-containing compound (A=Rb, Cs, NH₄), a RE-containing compound (RE=Sc, Y, La), a boron-containing compound, a fluorine-containing compound and the fluxing agents are 1.5-2.2:0.8-1.5:2.5-3.5:1.5-2.2:0-20; the cosolvents include at least one or more of AOH, A₂O, AF, ACl, ABr, ABF₄, A₃PO₄, A₃BO₃, ANO₃, A₂C₂O₄, A₂CO₃, AHCO₃, A₂SO₄, A₂HPO₄, AH₂PO₄, RE(NO₃)₃·6H₂O, B₂O₃, wherein A=Rb, Cs, NH₄; RE=Sc, Y, La.

5. A method for synthesizing series of fluorine-containing rare-earth borate compounds as claimed in claim 4, the series of fluorine-containing rare-earth borate compounds were synthesized by conventional solid-state reaction methods, or a hydrothermal method.

6. The synthesizing method for the series of fluorine-containing rare-earth borate compounds as claimed in claim 5, comprising the following steps:
The solid-state reaction method is used to prepare A₂REB₃O₆F₂ (A=Rb, Cs, NH₄; RE=Sc, Y, La) compounds, comprising the following steps: the mixture of a A-containing compound (A=Rb, Cs, NH₄), a RE-containing compound (RE=Sc, Y, La), a boron-containing compound, a fluorine-containing compound were thoroughly ground. Then, the mixture was put into a muffle furnace for calcination, with several intermediate grindings to get the A₂REB₃O₆F₂ (A=Rb, Cs, NH₄; RE=Sc, Y, La) single phase polycrystalline powder, wherein element A=Rb, Cs, NH₄ in the A-containing compound, element RE=Sc, Y, La in the RE-containing compound, element boron in the boron-containing compound, and element fluorine in the fluorine-containing compound are in a molar ratio of 1.5-2.2:0.8-1.5:2.5-3.5:1.5-2.2;
The hydrothermal method is used to prepare A₂REB₃O₆F₂ (A=Rb, Cs, NH₄; RE=Sc, Y, La) compounds, comprising the following steps: the mixture of a A-containing compound (A=Rb, Cs, NH₄), a RE-containing compound (RE=Sc, Y, La), a boron-containing compound, a fluorine-containing compound were combined with deionized water (0.1-50 mL) or the mineralizers (0.1-50 g), wherein element A=Rb, Cs, NH₄ in the A-containing compound, element RE=Sc, Y, La in the RE-containing compound, element boron in the boron-containing compound, and element fluorine in the fluorine-containing compound are in a molar ratio of 1.5-2.2:0.8-1.5:2.5-3.5:1.5-2.2; The mixture was loaded into Teflon-lined autoclave and subsequently sealed; The autoclave was heated, and then cooled to room temperature; finally, filter the solution containing powder to obtain the series of fluorine-containing rare-earth borate compounds;
The A-containing compounds (A=Rb, Cs, NH₄) include at least one or more of AOH, A₂O and alkali metal salt; alkali metal salt includes at least one or more of AF, ACl, ABr, ANO₃, A₂C₂O₄, A₂CO₃, AHCO₃, A₂SO₄, wherein A=Rb, Cs, NH₄; The RE-containing compounds (RE=Sc, Y, La) include at least one or more of RE₂O₃, REF₃, RE(NO₃)₃·6H₂O;
The boron-containing compounds include at least one or more of B₂O₃, H₃BO₃ and boron salt; the boron salt includes at least one or more of ABO₂, ABO₃, A₃BO₃, A₂B₄O₇, wherein A=Rb, Cs, NH₄;
The fluorine-containing compounds include at least one or more of AF, REF₃, wherein A=Rb, Cs, NH₄; RE=Sc, Y, La, and other fluorine-containing compounds include at least one or more of KBF₄, NaBF₄, KPF₆ and NH₄PF₆.7. The use as claimed in claim 1, wherein said nonlinear optical crystals, A₂REB₃O₆F₂ (A=Rb, Cs, NH₄; RE=Sc, Y, La) can be used as frequency converting apparatus, which generates a second, third, fourth or fifth harmonic of a 1064-nm Nd: YAG laser.

8. The use as claimed in claim 1, wherein said nonlinear optical crystals, A₂REB₃O₆F₂ (A=Rb, Cs, NH₄; RE=Sc, Y, La) can be used a harmonic generator, optical parametric and amplifying device, and optical waveguide device used in the ultraviolet region

9. The use as claimed in claim 1, wherein said nonlinear optical crystals, A₂REB₃O₆F₂ (A=Rb, Cs, NH₄; RE=Sc, Y, La) can be used in the preparation of multi-band frequency doubling devices or optics.

10. The use as claimed in claim 1, wherein said nonlinear optical crystals can be used as the second harmonic generator, the upper and lower frequency converters, optical parametric oscillator from infrared to ultraviolet.
